(19) United States
(12) Patent Application Publication
(10) Pub. No.: US 2019/0368031 A1
(43) Pub. Date: Dec. 5, 2019

(54) FIXTURE FOR PVD COATING OF SPADE BITS

(71) Applicant: Oerlikon Surface Solutions AG, Pfaffikon, Pfaffikon SZ (CH)

(72) Inventor: Phillip Joel LaForce, Taylor, MI (US)

(21) Appl. No.: 15/992,574

(22) Filed: May 30, 2018

(51) Int. Cl. C23C 14/50

(52) U.S. Cl. CPC C23C 14/505; B23B 51/0009

(57) ABSTRACT

A fixture assembly for supporting a workpiece having opposing side walls defining a notch. The fixture assembly includes a base and a first member extending from a surface of the base. The first member has an outward facing surface. A second member extends from the surface of the base. The first member is parallel to the first member and has an outward facing surface. At least one adjusting assembly is configured for moving at least one of the first member and the second member to adjust a distance between the outward facing surfaces of the first member and the second member wherein moving at least one of the first member and the second member increases the distance between the outward facing surfaces of the first and second members and causes the outward facing surfaces to engage the opposing side walls to clamp the workpiece to the first and second members.

### CROSS-REFERENCE TO RELATED APPLICATIONS

None

### FIELD OF THE INVENTION

This application relates generally to a fixture for spade bits, and more particularly, to a fixture for holding the spade bits during a physical vapor deposition (PVD) coating process.

### BACKGROUND OF THE INVENTION

Conventionally, coating spade bits required either coating one side of the spade bits at a time, or using hooks, rods, etc. to hold the spade bits. The two step coating process or the hooks, or rods often create shadows or require masking of certain areas of the spade bits. In some instances, magnets are used to hold the spade bits during the coating process. However, the magnets are prone to physical and magnetic degradation and tend to result in loose magnetic particles being left in the coating vessel. This, in turn, causes defects and inclusions in the coating.

The present invention provides a fixture for allowing coating one or more spade bits.

### BRIEF SUMMARY OF THE INVENTION

In accordance with one aspect, there is provided a fixture assembly for supporting a workpiece having opposing side walls defining a notch. The fixture assembly including a base, a first member extending from a surface of the base, the first member having an outward facing surface and a second member extending from the surface of the base and parallel to the first member. The second member having an outward facing surface. At least one adjusting assembly configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

The fixture assembly may be configured such that at least one of the first member and the second member includes a tab dimensioned to be slideably received into a slot formed in the base.

The fixture assembly may be configured such that at least one adjusting assembly includes a screw element for increasing the distance between the outward facing surfaces of the first member and the second member when the screw element is turned in a first direction

The fixture assembly may be configured such that the screw element engages a first block attached to the first member and a second block attached to the second member. The screw element may be in threaded engagement with the first block.

The fixture assembly may include a plurality of adjusting assemblies spaced apart along the first member and the second member.

The fixture assembly may be configured such that the first member and the second member are elongated L-shaped elements each having a base portion disposed parallel to the surface of the base and a leg portion extending from the base portion. The outward facing surfaces of the first member and the second member may be disposed on the leg portion.

The fixture assembly may be configured such that the fixture assembly is one of a plurality of assemblies attached to a column.

The fixture assembly may be configured such that the base includes at least one mounting hole for allowing at least one fastener to secure the base to the column.

The fixture assembly may be configured such that the workpiece is a spade bit

The fixture assembly may be configured such that a plurality of workpieces is attached along a length of the first member and the second member.

According to another aspect there is provided a mounting assembly for supporting a plurality of workpieces having opposing side walls defining a notch. The mounting assembly including a column having a rotational axis and a plurality of fixture assemblies attached to the column. Each fixture assembly has a plurality of workpieces attached thereto. Each fixture assembly includes a base and a first member extending from a surface of the base. The first member has an outward facing surface. A second member extends from the surface of the base and is parallel to the first member. The second member has an outward facing surface. At least one adjusting assembly is configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

The mounting assembly may be configured such that the workpiece is a spade bit.

The mounting assembly may be configured such that the at least one adjusting assembly includes a screw element for increasing the distance between the outward facing surfaces of the first member and the second member when the screw element is turned in a first direction.

The mounting assembly may be configured such that the screw element engages a first block attached to the first member and a second block attached to the second member. The screw element is in threaded engagement with the first block

A coating assembly for applying a coating to a plurality of workpieces using a PVD coating process. The coating assembly including a chamber, a vacuum device attached to the chamber for drawing a vacuum on the chamber, at least one target disposed in the chamber for supplying a material to be coated onto the workpieces and a mounting assembly. The mounting assembly includes a column having a rotational axis; and a plurality of fixture assemblies attached to the column. Each fixture assembly has a plurality of workpieces attached thereto. Each fixture assembly includes a base and a first member extending from a surface of the base. The first member has an outward facing surface. A second member extends from the surface of the base and is parallel to the first member. The second member has an outward facing surface. At least one adjusting assembly is configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

The coating assembly may be configured such that a motor is attached to the mounting assembly for rotating the mounting assembly about the rotational axis.

The coating assembly may be configured such that the workpiece is a spade bit.

The coating assembly may be configure such that at least one adjusting assembly includes a screw element for increasing the distance between the outward facing surfaces of the first member and the second member when the screw element is turned in a first direction.

The coating assembly may be configured such that the screw element engages a first block attached to the first member and a second block attached to the second member. The screw element is in threaded engagement with the first block.

### BRIEF DESCRIPTION OF THE DRAWINGS

FIG. 1 is a top perspective view of a fixture assembly showing a spade bit spaced from the fixture assembly;

FIG. 2 is a top perspective view of the fixture assembly of FIG. 1 showing a plurality of spade bits disposed on the fixture assembly;

FIG. 3 is a top plan view of the fixture assembly of FIG. 1;

FIG. 4 is a section view taken along line 4-4 of FIG. 3;

FIG. 5 is a section view taken along line 5-5 of FIG. 3;

FIG. 6 is a section view taken along line 6-6 of FIG. 3;

FIG. 7 is a sectional view showing the fixture assembly of FIG. 1 in a first position and a spade bit positioned on the fixture assembly;

FIG. 8 is a sectional view showing the fixture assembly of FIG. 1 in a second position and a spade bit positioned on the fixture assembly;

FIG. 9 is a front perspective view of a mounting assembly including a plurality of fixture assemblies of FIG. 1 attached to a column;

FIG. 10 is a bottom plan view of the mounting assembly of FIG. 9; and

FIG. 11 is a schematic view of a coating assembly including the mounting assembly of FIG. 9 disposed in a chamber.

### DESCRIPTION OF EXAMPLE EMBODIMENTS

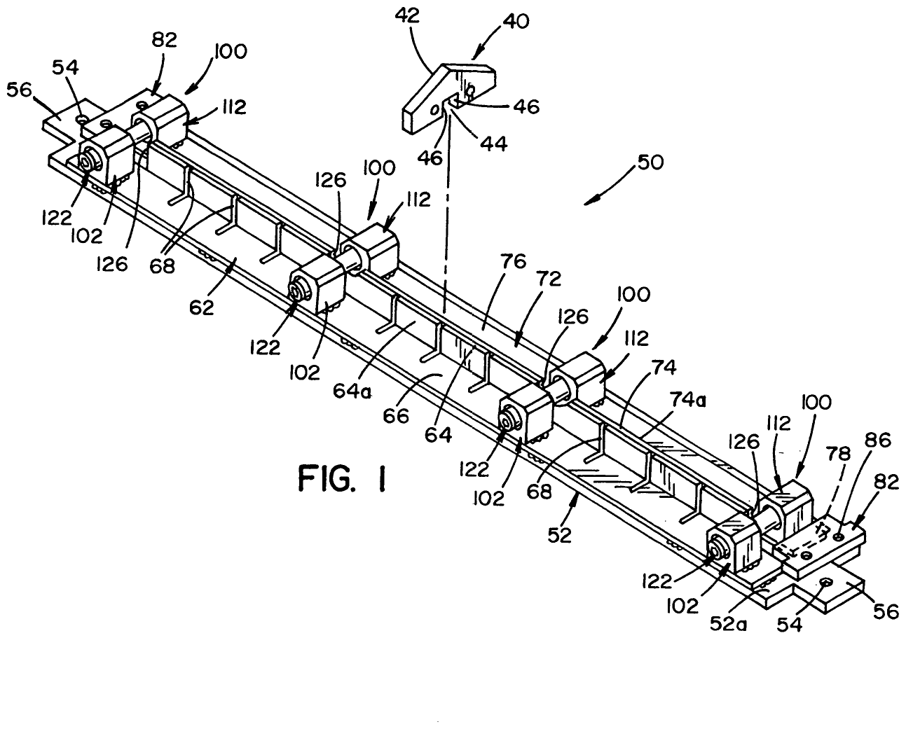

Referring now to the drawings, FIG. 1 shows a fixture assembly 50 for holding a plurality of workpieces, such as spade bits 40. The fixture assembly 50, in general, includes a base 52, a first member 62 and a second member 72 and at least one adjusting assembly 100.

As shown, the base 52 is a generally flat elongated member having a plurality of mounting holes 54 for securing the base 52 to a column 130, as described in detail below. As shown, the mounting holes 54 are positioned in tabs 56. It is contemplated that the mounting holes 54 could be placed at spaced apart location along the length of the base 52.

As shown, the first member 62 is secured to an upper surface 52a of the base 52 using conventional mounting methods, such as, but not limited to, welding, fasteners, adhesives, etc. The first member 62 includes a leg portion 64 and a base portion 66. As shown, the first member 62 is generally L-shaped such that the leg portion 64 is perpendicular to the base portion 66. As shown, a plurality of slots 68 may extend through the leg portion 64 and partially through the base portion 66 at spaced apart locations along the length of the first member 62. As shown, the first member 62 is a fixed member that is attached to the base 52. It is contemplated that the first member 62 may alternatively be movable relative to the base 52, similar to the second member 72, described in detail below.

The second member 72 is positioned to extend along the length of the first member 62 and to be parallel to the first member 62. The second member 72 is slideably retained on the base 52, as described in detail below.

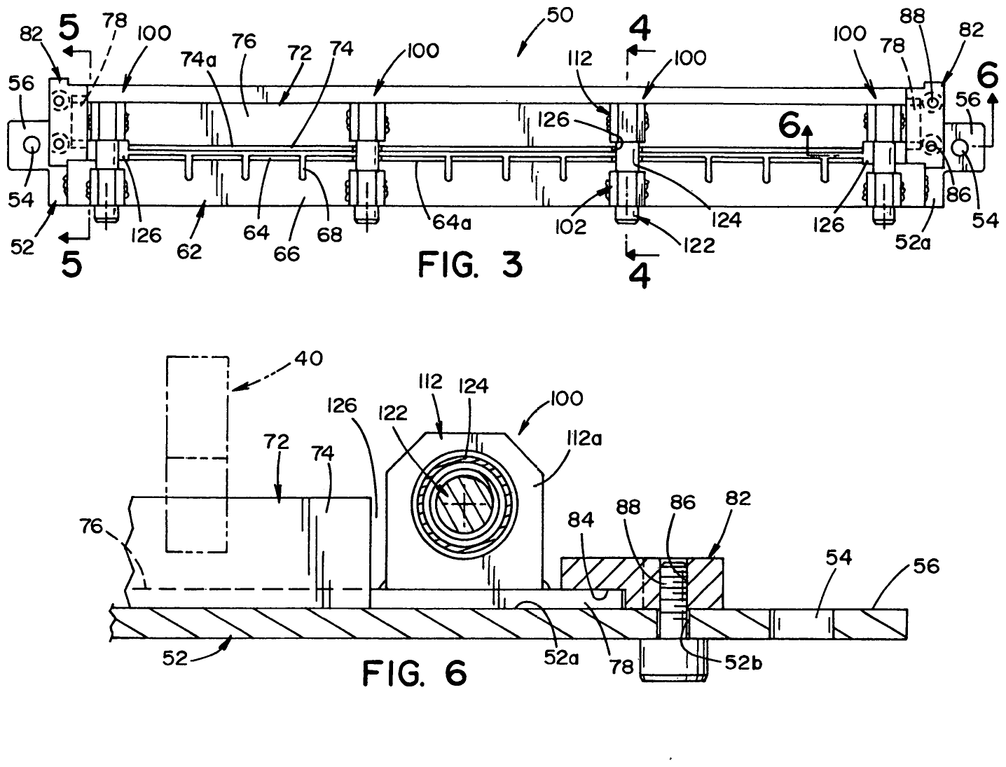

Referring to FIGS. 1 and 3, the second member 72 includes a leg portion 74 and a base portion 76. As shown the second member 72 is generally L-shaped such that the leg portion 74 is perpendicular to the base portion 76. Referring to FIG. 6, a tab 78 extends from opposite ends for the second member 72. The tabs 78 are dimensioned and positioned to be slideably retained by respective blocks 82. As shown, the second member 72 is a movable member that is movable relative to the base 52. Accordingly, one or both of the first and second members may be movable.

Blocks 82 each includes a recess 84 that is dimensioned to define a slot between the blocks 82 and the upper surface 52a of the base 52. The blocks 82 include threaded holes 86 that are dimensioned and positioned to align with mating holes 52b in the base 52. Fasteners 88 extend through the holes 52b, 86 for securing the blocks 82 to the base 52.

Referring to FIG. 1, one or more adjusting assemblies 100 are disposed along the length of the first member 62 and the second member 72. Each adjusting assembly 100 includes a first block 102, a second block 112 and a screw element 122.

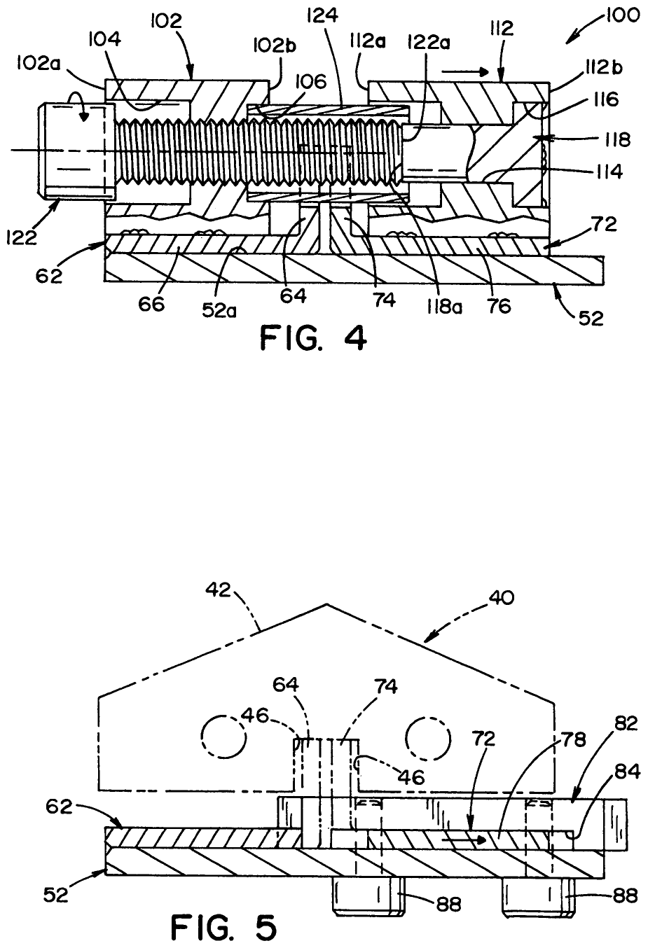

The first block 102 is attached to the first member 62. As shown, the first block 102 is fixed to an upper surface of the base portion 66 of the first member 62. Referring to FIG. 4, a counter-bored, threaded hole 104 extends through the first block 102 from a first surface 102a to a second surface 102b of the first block 102. A counter-bore 106 is formed in the second surface 102b around the hole 104. The first block 102 is secured to the upper surface of the base portion 66 using conventional mounting methods, such as, but not limited to, welding, fasteners, adhesives, etc.

The second block 112 is attached to the second member 72. As shown, the second block 112 is fixed to an upper surface of the base portion 76 of the second member 72. A counter-bored hole 114 extends through the second block 112 from a first surface 112a to a second surface 112b of the second block 112. A counter-bore 116 is formed in the second surface 112b around the hole 114. A plug 118 is positioned in the hole 114 and the counter-bore 116. As shown the plug 118 may be welded to the second block 112. The second block 112 is secured to the upper surface of the base portion 76 using conventional mounting methods, such as, but not limited to, welding, fasteners, adhesives, etc.

The first block 102 and the second block 112 are positioned and dimensioned such that the hole 104 in the first block 102 aligns with the hole 114 in the second block 112. The screw element 122 is dimensioned and positioned to be threaded into the hole 104 such that a distal end 122a of the screw element 122 engages an end 118a of the plug 118. A sleeve 124 is positioned over a threaded portion of the screw element 122 to protect the screw during a coating process, as described in detail below.

Referring to FIG. 1, it is contemplated that a plurality of notches 126 may be formed in the leg portions 64, 74 of the first member 62 and the second member 72 at a plurality of distinct locations for allowing clearance around the adjusting assemblies 100.

The spade bits 40 are dimensioned to be positioned on the first member 62 and the second member 72. Each spade bit 40 includes a sharp edge 42 and a notch 44. As shown, the notch 44 is rectangular-in-shape with two inward facing side walls 46. It is contemplated that each spade bit 40 may be dimensioned and positioned such that the notch 44 in the spade bit 40 aligns with the slot 68 in the leg portion 64 of the first member 62. As such, the spade bits 40 may be properly positioned to allow for uniform and repeatable application of a coating material, as described in detail below. Other workpieces may be used provided that they have a notch with inward facing side walls.

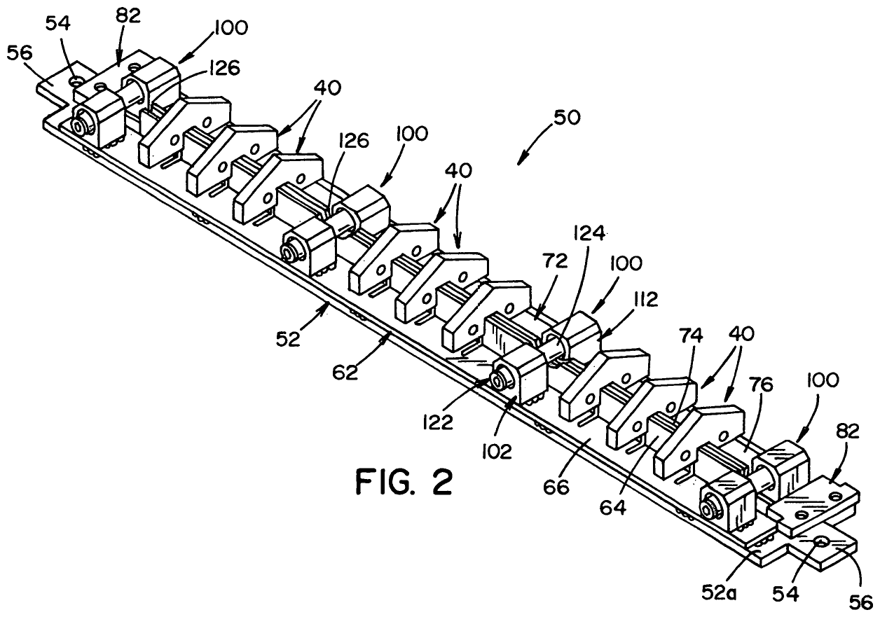

The fixture assembly 50 will now be described with respect to the operation of the same. As discussed in detail above, the fixture assembly 50 is configured to allow spade bits 40 to be mounted to the fixture assembly 50. As shown in FIG. 2, a plurality of spade bits 40 may be positioned to align with the plurality of slots 68 in the first member 62.

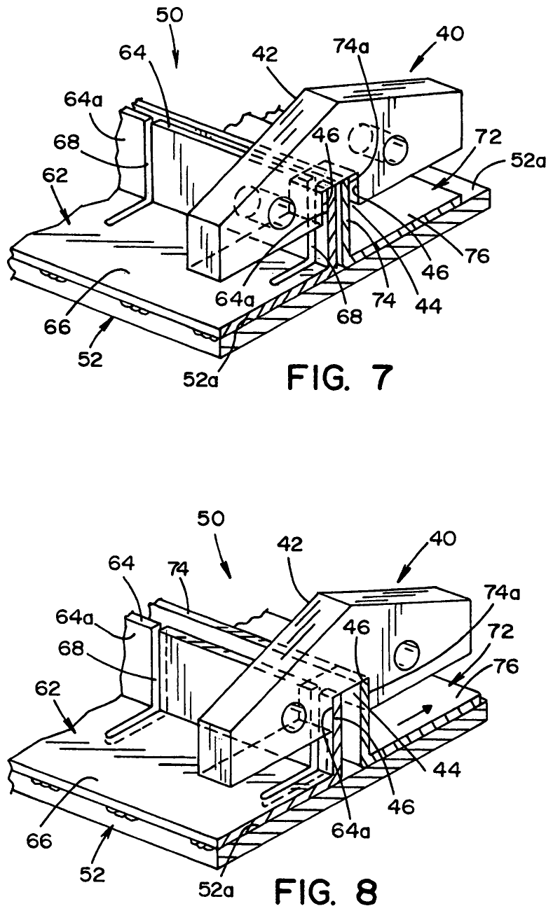

In particular, as referring to FIG. 7, the spade bit 40 may be positioned over the leg portions 64, 74 of the first member 62 and the second member 72. As shown, the second member 72 is in a first position wherein the distance between an outward facing surface 74a of the leg portion 74 and an outward facing surface 64a of the leg portion 64 is less than the distance between the inward facing side walls 46 of the spade bit 40. The spade bit 40 may freely side over the edges of the leg portions 64, 74.

Referring to FIG. 4, as the screw element 122 is turned, the distal end 122a of the screw element 122 engages the distal end 118a of the plug 118 thereby causing the plug 118, the second block 112 and the second member 72 to slide away from the first member 62 (as represented by the arrows in FIGS. 4, 5 and 8). In the embodiment shown in FIG. 2, a plurality of spade bits 40 is disposed on the fixture assembly 50. The fixture assembly 50 includes a plurality of adjusting assemblies 100. It is contemplated that the screw elements 122 for each adjusting assemblies 100 may be sequentially turned or simultaneously turned so that the second member 72 remains parallel to the first member 62 as the second member 72 slides away from the first member 62. In the embodiment wherein the first member 62 is movable, the adjusting assemblies 100 may be configured to cause the first member 62 and/or the second member 72 to move.

Referring to FIG. 8, the screw elements 122 may continue to turn until the outward facing surface 74a of the leg portion 74 and the outward facing surface 64a of the leg portion 64 both engage the inward facing side walls 46 of the spade bit 40. The screw elements 122 may be turned until the force exerted by the leg portions 64, 74 on the notch 44 is sufficient to retain the spade bits 40 on the fixture assembly 50.

Subsequently, the fixture assembly 50 may be placed in a PVD chamber (not shown) wherein the spade bits 40 are coated. As shown in FIG. 8, a gap is formed between the leg portions 64, 74 such that the coating material may contact a portion of the notch 44 not contacted by the leg portions 64, 74. The only contact between the spade bit 40 and the fixture assembly 50 is along the inward facing side walls 46 of the notch 44. The coating material may thus freely flow around the spade bit 40 and apply a uniform coating to all the remaining surfaces of the spade bit 40.

To remove the spade bits 40 from the fixture assembly 50, the screw elements 122 are turned in the reverse direction to release the pressure on the spade bit 40 applied by the second member 72. It may be necessary for the user to displace the second member 72 toward the first member 62 to allow the spade bits 40 to be freed from the fixture assembly 50.

As shown, the screw elements 122 are threaded into the first block 102. It is contemplated that at least one of the screw elements 122 may be captured by a fixing member (e.g., a snap ring) (not shown) into the first block 102 such that the screw element 122 may freely rotate relative to the first block 102. The threaded portion of the screw element 122 may be threaded into the second block 112 such that rotation of the screw element 122 in one direction draws the first block 102 (and the first member 62) and the second block 112 (and the second member 72) toward each other and rotation of the screw element 122 in the opposite direction moves the first block 102 and the second block 122 away from each other. The positive movement of the first member 62 and the second member 72 by this screw element 122 reduces the need for the user to manually displace or move the first member 62 and the second member 72 away from each other when freeing the spade bits 40 from the fixture assembly 50.

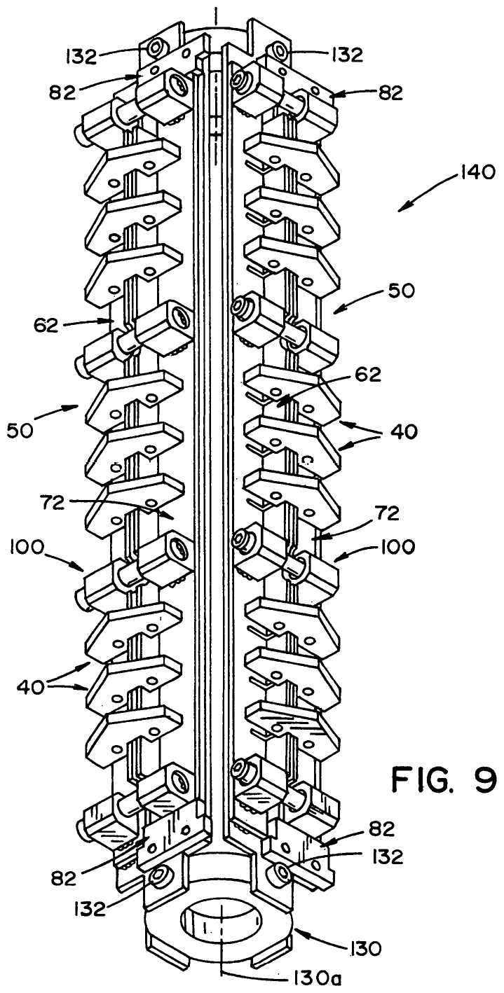

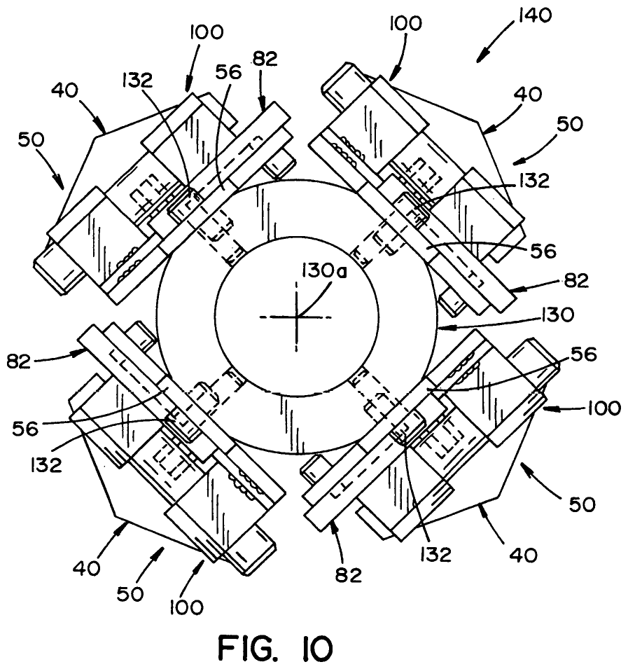

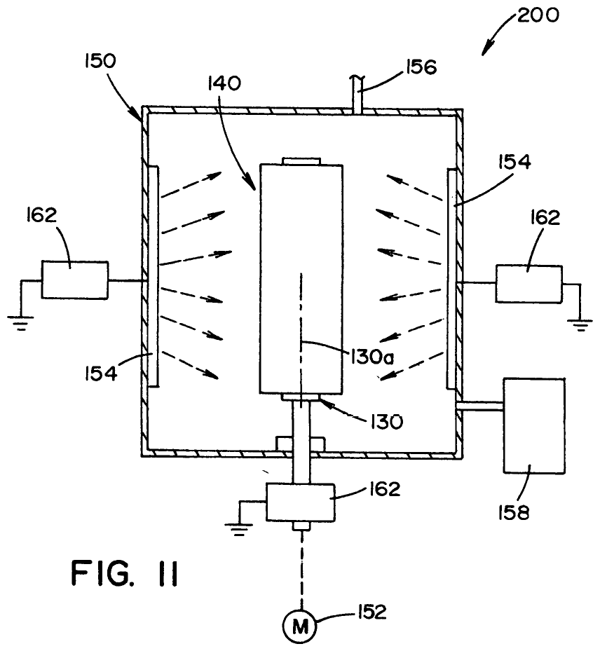

Referring to FIGS. 9 and 10, it is contemplated that a column 130 may be provided for allowing a plurality of fixture assemblies 50 to be mounted thereto to form a mounting assembly 140. Fasteners 132 may be provided for securing the fixture assemblies 50 to the column 130. As shown, the fixture assemblies 50 may be positioned such that there is ample space around the spade bits 40 for the coating material to flow uniformly during a PVD coating process. The column 130 includes a rotational axis 130a for rotating the mounting assembly 140.

Referring to FIG. 11, a coating assembly 200 may include a vacuum chamber 150 for receiving the mounting assembly 140. It is contemplated that the mounting assembly 140 may be attached to a motor 152 for rotating the mounting assembly 140 within the chamber 150. One or more targets 154 may be positioned in the chamber 150 for supplying a material to be coated onto the spade bits 40. It is contemplated that an inlet 156 may extend through a wall of the chamber 150 for supplying a gas to the chamber 150. A vacuum system 158 may be attached to the chamber 150 for drawing a vacuum in the chamber 150 during the PVD coating process. One or more sources of electrical potential 162, e.g., batteries, may be connected to the targets 154 and the mounting assembly 140 for generating the required electrical potential for the PVD coating process. It is contemplated that during the PVD coating process that the motor 152 may cause the mounting assembly 140 to rotating within the chamber 150 such that the material released by the targets 154 may uniformly coat the spade bits 40.

The invention has been described with reference to the example embodiments described above. Modifications and alterations will occur to others upon a reading and understanding of this specification. Examples embodiments incorporating one or more aspects of the invention are intended to include all such modifications and alterations insofar as they come within the scope of the appended claims and their equivalents.

What is claimed is:

1. A fixture assembly for supporting a workpiece having opposing side walls defining a notch, the fixture assembly comprising:
a base;
a first member extending from a surface of the base, the first member having an outward facing surface;
a second member extending from the surface of the base and being parallel to the first member, the second member having an outward facing surface; and
at least one adjusting assembly configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

2. The fixture assembly according to claim 1, at least one of the first member and the second member including a tab dimensioned to be slideably received into a slot formed in the base.

3. The fixture assembly according to claim 1, wherein the at least one adjusting assembly includes a screw element for increasing the distance between the outward facing surfaces of the first member and the second member when the screw element is turned in a first direction.

4. The fixture assembly according to claim 3, wherein the screw element engages a first block attached to the first member and a second block attached to the second member and wherein the screw element is in threaded engagement with the first block.

5. The fixture assembly according to claim 1, comprising a plurality of adjusting assemblies spaced apart along the first member and the second member.

6. The fixture assembly according to claim 1, wherein the first member and the second member are elongated L-shaped elements each having a base portion disposed parallel to the surface of the base and a leg portion extending from the base portion and wherein the outward facing surfaces of the first member and the second member are disposed on the leg portion.

7. The fixture assembly according to claim 1, wherein the fixture assembly is one of a plurality of assemblies attached to a column.

8. The fixture assembly according to claim 7, wherein the base includes at least one mounting hole for allowing at least one fastener to secure the base to the column.

9. The fixture assembly according to claim 1, wherein the workpiece is a spade bit.

10. The fixture assembly according to claim 1, wherein a plurality of workpieces are attached along a length of the first member and the second member.

11. A mounting assembly for supporting a plurality of workpieces having opposing side walls defining a notch, the mounting assembly comprising:
a column having a rotational axis; and
a plurality of fixture assemblies attached to the column, each fixture assembly having a plurality of workpieces attached thereto, each fixture assembly comprising:
a base;
a first member extending from a surface of the base, the first member having an outward facing surface;
a second member extending from the surface of the base and being parallel to the first member, the second member having an outward facing surface; and
at least one adjusting assembly configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

12. The mounting assembly according to claim 11, wherein the workpiece is a spade bit.

13. The mounting assembly according to claim 11, wherein the at least one adjusting assembly includes a screw element for increasing the distance between the outward facing surfaces of the first member and the second member when the screw element is turned in a first direction.

14. The mounting assembly according to claim 13, wherein the screw element engages a first block attached to the first member and a second block attached to the second member and wherein the screw element is in threaded engagement with the first block.

15. A coating assembly for applying a coating to a plurality of workpieces using a PVD coating process, the coating assembly comprising:
a chamber;
a vacuum device attached to the chamber for drawing a vacuum on the chamber;
at least one target disposed in the chamber for supplying a material to be coated onto the workpieces; and
a mounting assembly comprising:
a column having a rotational axis; and
a plurality of fixture assemblies attached to the column, each fixture assembly having a plurality of workpieces attached thereto, each fixture assembly comprising:
a base;
a first member extending from a surface of the base, the first member having an outward facing surface;
a second member extending from the surface of the base and being parallel to the first member, the second member having an outward facing surface; and
at least one adjusting assembly configured for moving at least one of the first member and the second member to adjust a distance between the outward facing surfaces of the first member and the second member wherein moving at least one of the first member and the second member increases the distance between the outward facing surfaces of the first member and the second member and causes the outward facing surfaces to engage the opposing side walls to clamp the workpiece to the first member and the second member.

16. The coating assembly according to claim 15, further comprising a motor attached to the mounting assembly for rotating the mounting assembly about the rotational axis.

17. The coating assembly according to claim 15, wherein the workpiece is a spade bit.

18. The coating assembly according to claim 15, wherein the at least one adjusting assembly includes a screw element for increasing the distance between the outward facing surfaces of the first member and the second member when the screw element is turned in a first direction.

19. The coating assembly according to claim 18, wherein the screw element engages a first block attached to the first member and a second block attached to the second member and wherein the screw element is in threaded engagement with the first block.
